(19) United States
(12) Patent Application Publication
(10) Pub. No.: US 2020/0211984 A1
(43) Pub. Date: Jul. 2, 2020

(54) ELECTRONIC DEVICE PACKAGE STRUCTURE AND MANUFACTURING METHOD THEREOF

(71) Applicant: Industrial Technology Research Institute, Hsinchu (TW)

(72) Inventors: Jui-Chang Chuang, Kaohsiung City (TW); Chen-Tsai Yang, Taoyuan City (TW); Wei-Yuan Cheng, Hsinchu County (TW)

(73) Assignee: Industrial Technology Research Institute, Hsinchu (TW)

(21) Appl. No.: 16/404,765

(22) Filed: May 7, 2019

(30) Foreign Application Priority Data
Dec. 27, 2018 (TW) 107147352

(51) Int. Cl. H01L 23/00; H01L 23/31; H01L 23/538; H01L 21/48; H01L 21/56

(52) U.S. Cl. CPC H01L 23/562; H01L 23/3121; H01L 23/5383; H01L 23/5386; H01L 23/5389; H01L 24/20; H01L 2924/35121; H01L 21/4857; H01L 21/4853; H01L 21/565; H01L 2224/214; H01L 2924/3512; H01L 24/19

(57) ABSTRACT

An electronic device package structure and a manufacturing method thereof are provided. The electronic device package structure includes a first electronic device layer, a second electronic device layer, and a filling layer disposed between the first electronic device layer and the second electronic device layer, wherein the Young's modulus of the second electronic device layer is less than or equal to the Young's modulus of the first electronic device layer, and the Young's modulus of the filling layer is less than the Young's modulus of the second electronic device layer, and the ratio of the Young's modulus of the first electronic device layer to the Young's modulus of the filling layer is 10 to 1900 and the ratio of the Young's modulus of the second electronic device layer to the Young's modulus of the filling layer is 7.6 to 1300.

### CROSS-REFERENCE TO RELATED APPLICATION

This application claims the priority benefit of Taiwan application serial no. 107147352, filed on Dec. 27, 2018. The entirety of the above-mentioned patent application is hereby incorporated by reference.

### TECHNICAL FIELD

The disclosure relates to an electronic device package structure and a manufacturing method thereof, and also relates to an electronic device package structure having a plurality of neutral surfaces and a manufacturing method thereof.

### BACKGROUND

With the rapid development of electronic goods, fixed and rigid products have been unable to meet the needs of the consumer market. For example, an electronic device for a wearable device needs to match the wear contour to improve wear comfort, and therefore the electronic device is in a bent state when worn on the human body. However, when the electronic device is in a bent state, elements in the electronic device are prone to issues such as delamination or cracking due to stress.

In general, when the electronic device is subjected to stress, there is a neutral axis of stress balance between the compressive stress region and the tensile stress region. The junction of the compressive stress region and the tensile stress region forms a neutral surface when viewed from the overall device. In order to solve the issue of stress distribution, the weaker part in the electronic structure is generally placed in the stress neutral surface region. However, conventional electronic devices have only one neutral surface, and most of the members in the electronic device are still susceptible to the influence of stress. Accordingly, how to solve the existing issues of stress distribution and poor flex resistance of the electronic device is the subject of current research.

### SUMMARY

An embodiment of the disclosure provides an electronic device package structure including a first electronic device layer, a second electronic device layer and a filling layer disposed between the first electronic device layer and the second electronic device layer. The Young's modulus of the second electronic device layer is less than or equal to the Young's modulus of the first electronic device layer, and the Young's modulus of the filling layer is less than the Young's modulus of the second electronic device layer, and the ratio of the Young's modulus of the first electronic device layer to the Young's modulus of the filling layer is 10 to 1900 and the ratio of the Young's modulus of the second electronic device layer to the Young's modulus of the filling layer is 7.6 to 1300.

Another embodiment of the disclosure provides an electronic device package structure including an electronic device layer, a functional structure, and a filling layer disposed between the electronic device layer and the functional structure. The Young's modulus of the functional structure is less than or equal to the Young's modulus of the electronic device layer, and the Young's modulus of the filling layer is less than the Young's modulus of the functional structure, the thickness ratio of the filling layer to the electronic device layer is 0.6 to 10, and the thickness ratio of the filling layer to the functional structure is 1.2 to 50.

Yet another embodiment of the disclosure provides a manufacturing method of an electronic device package structure, including the following steps. A first electronic device layer having a first thickness and a first Young's modulus is formed. A second electronic device layer having a second thickness and a second Young's modulus is formed. A filling layer is formed between the first electronic device layer and the second electronic device layer, wherein the filling layer is adjusted to have a third Young's modulus according to the first Young's modulus of the first electronic device layer and according to the second Young's modulus of the second electronic device layer, and the third Young's modulus is less than the first Young's modulus and less than the second Young's modulus. The filling layer is adjusted to have a third thickness according to the first thickness of the first electronic device layer and according to the second thickness of the second electronic device layer.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a cross section of an electronic device package structure according to an embodiment of the disclosure.

FIG. 2 is a cross section of an electronic device package structure according to another embodiment of the disclosure.

FIG. 3A and FIG. 3B are schematic diagrams illustrating configurations of chips of an electronic device package structure according to an embodiment of the disclosure.

FIG. 4A and FIG. 4B are cross sections of an electronic device package structure according to another embodiment of the disclosure.

FIG. 5A to FIG. 5C are top views of an electronic device package structure according to other embodiments of the disclosure.

FIG. 6 is a cross section along section line A-A′ in the electronic device package structure shown in FIG. 5A.

FIG. 7 is a plot showing the normalized strain on an electronic device package structure having a plurality of neutral surfaces with respect to the position.

FIG. 8A is a plot showing the normalized strain on an electronic device package structure having a single neutral surface with respect to the position.

FIG. 8B is a plot showing the normalized strain on an electronic device package structure having a plurality of neutral surfaces with respect to the position.

### DESCRIPTION OF THE EMBODIMENTS

In the following, embodiments of the disclosure are described in detail with reference to figures. However, it should be mentioned that, the figures are all simplified schematics showing the basic structure or implementation of the disclosure in an illustrative manner. Therefore, only members and combinations pertinent to the present application are shown, and the members shown in the figures are not drawn to scale in terms of the number, shape, and size of actual implementation. Certain size ratios and other relating size ratios are exaggerated or simplified to provide a clearer description.

An embodiment of the disclosure provides an electronic device package structure, wherein by adjusting the Young's moduli and thicknesses of different members in the electronic device package structure, delamination or cracking does not occur to the electronic device package structure in a bent state.

FIG. 1 is a cross section of an electronic device package structure according to an embodiment of the disclosure.

Referring to FIG. 1, an electronic device package structure 100 according to an embodiment of the disclosure includes a first electronic device layer 110, a second electronic device layer 120, and a filling layer 130. The filling layer 130 is disposed between the first electronic device layer 110 and the second electronic device layer 120. A conductive through hole 132 may be disposed in the filling layer 130. The first electronic device layer 110 includes a first chip 116, a first redistribution layer structure 114, and a first signal connection structure 118 disposed between the first chip 116 and the first redistribution layer structure 114. The first redistribution layer structure 114 is located between the first chip 116 and the filling layer 130. The second electronic device layer 120 includes a second chip 126, a second redistribution layer structure 124, and a second signal connection structure 128 disposed between the second chip 126 and the second redistribution layer structure 124. The second redistribution layer structure 124 is located between the second chip 126 and the filling layer 130. The second electronic device layer 120 may further include a functional structure 140 such that the second chip 126 is located between the functional structure 140 and the second redistribution layer structure 124.

According to an embodiment of the disclosure, the thickness of the first electronic device layer 110 may be between 50 microns and 300 microns, such as 100 microns, 150 microns, 200 microns, or 250 microns. The thickness of the second electronic device layer 120 may be between 10 microns and 300 microns, such as 50 microns, 100 microns, 150 microns, 200 microns, or 250 microns. The thickness of the first electronic device layer 110 may be the same as the thickness of the second electronic device layer 120. Alternatively, the thickness of the first electronic device layer 110 may be different from the thickness of the second electronic device layer 120. The thickness of the filling layer 130 may be between 200 microns and 500 microns, such as 250 microns, 300 microns, 350 microns, 400 microns, or 450 microns.

According to an embodiment of the disclosure, the ratio of the thickness of the filling layer 130 to the thickness of the first electronic device layer 110 may be between 0.1 and 10. In another embodiment, the ratio of the thickness of the filling layer 130 to the thickness of the first electronic device layer 110 may be 0.6 to 10. The ratio of the thickness of the filling layer 130 to the thickness of the second electronic device layer 120 may be between 0.1 and 50. In another embodiment, the ratio of the thickness of the filling layer 130 to the thickness of the second electronic device layer 120 may be 1.2 to 50.

When the thickness of the first electronic device layer 110, the thickness of the second electronic device layer 120, and the thickness of the filling layer 130 are within the above ratio ranges, the electronic device package structure may have a plurality of neutral surfaces while in a bent state to avoid delamination or cracking.

According to an embodiment of the disclosure, the Young's modulus of the first electronic device layer 110 may be between 130 GPa and 180 GPa. The Young's modulus of the second electronic device layer 120 may be between 115 GPa and 130 GPa. The Young's modulus of the filling layer 130 may be between 0.1 GPa and 5 GPa, such as 0.2 GPa, 0.5 GPa, 1 GPa, 2 GPa, 3 GPa, 4 GPa, or 5 GPa.

According to an embodiment of the disclosure, the ratio of the Young's modulus of the first electronic device layer 110 to the Young's modulus of the filling layer 130 may be between 10 and 1900. In another embodiment, the ratio of the Young's modulus of the first electronic device layer 110 to the Young's modulus of the filling layer 130 may be between 26 and 1800. The ratio of the Young's modulus of the second electronic device layer 120 to the Young's modulus of the filling layer 130 may be between 7.6 and 1300. In another embodiment, the ratio of the Young's modulus of the second electronic device layer 120 to the Young's modulus of the filling layer 130 may be between 23 and 1300.

By controlling the thicknesses and Young's moduli of the first electronic device layer 110, the second electronic device layer 120, and the filling layer 130 within the above ranges, the electronic device package structure 100 according to an embodiment of the disclosure may have a first neutral surface located in the first electronic device layer 110, a second neutral surface located in the second electronic device layer 120, and a third neutral surface located in the filling layer 130. In particular, according to an embodiment of the disclosure, the first neutral surface is located between the first chip 116 and the filling layer 130, in another embodiment, the first neutral surface is located between the first chip 116 and the first redistribution layer structure 114. According to an embodiment of the disclosure, the second neutral surface is located between the second chip 126 and the filling layer 130, in another embodiment, the second neutral surface is located between the second chip 126 and the second redistribution layer structure 124. In other words, according to the electronic device package structure 100 of an embodiment of the disclosure, at least two of the plurality of neutral surfaces thereof are located at the junction or connection interface of the electronic device. That is, the first neutral surface and the second neutral surface of the electronic device package structure 100 according to an embodiment of the disclosure may be located at the electronic device junction or connection interface. In this way, strain on the junction of the electronic device package structures in a bent state may be reduced, that is, the amount of strain is reduced when the electronic device package structure is bent, so that the electronic device package structure may be more resistant to flexing.

In general, the portion most susceptible to stress in an electronic device is the connection structure where the chip is mounted (e.g., a copper column at which the chip is bonded to the redistribution layer structure). Therefore, when the neutral surface is located at the connection structure, the situation in which the connection structure is affected by stress and breaks may be alleviated. That is to say, a package structure having a plurality of neutral surfaces may have improved flex resistance.

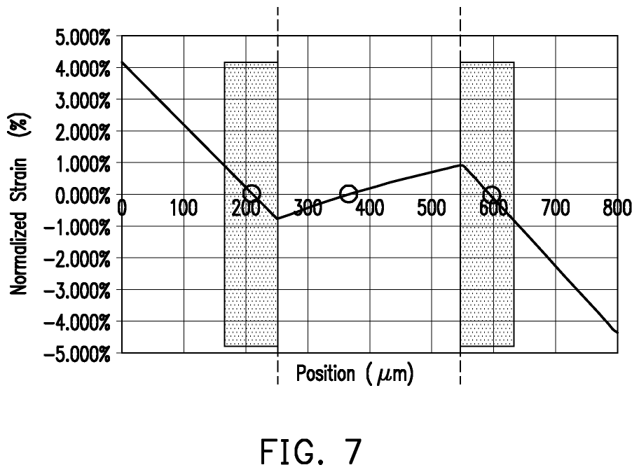

FIG. 7 is a plot showing the normalized strain on an electronic device package structure having a plurality of neutral surfaces with respect to the position (in a thickness direction). Here, the Young's moduli of the first and second electronic device layers of the electronic device package structure are 131 GPa, and the Young's modulus of the filling layer is 3 GPa. The Young's moduli of the first and second electronic device layers and the filling layer are merely examples, and the disclosure is not limited thereto. For example, the Young's modulus of the filling layer may be less than or equal to 5 GPa. The 0-position shown by the horizontal axis in FIG. 7 corresponds to the top surface of the electronic device package structure and the position is extended toward the bottom surface in the thickness direction, and the location where the normalized strain is 0 is where the neutral surface is located. The dotted line on the left in FIG. 7 represents the interface between the first electronic device layer 110 and the filling layer 130, and the dotted line on the right represents the interface between the filling layer 130 and the second electronic device layer 120. That is, the 0-micron to 250-micron positions shown on the horizontal axis correspond to the position of the first electronic device layer 110 (i.e., the thickness of the first electronic device layer 110 is 250 microns), the 250-micron to 550-micron positions correspond to the position of the filling layer 130 (i.e., the thickness of the filling layer is 300 microns), and the 550-micron to 800-micron positions correspond to the position of the second electronic device layer 120 (i.e., the thickness of the second electronic device layer 120 is 250 microns).

The rectangles with black dots in FIG. 7 correspond to the position of the connection structure in the electronic device package structure. In FIG. 7, it may be observed that one neutral surface is at each rectangle. When the electronic device package structure is in a bent state, the connection structure is subjected to normalized strain of about −0.8% to 0.8%, depending on the thickness of the connection structure. That is, compared to an electronic device package structure only having a single neutral surface and having average normalized strain of 1% to 1.5%, the average normalized strain at the connection structure of an electronic device package structure having a plurality of neutral surfaces according to an embodiment of the disclosure may significantly reduce. Therefore, the flex resistance of the electronic device package structure according to the disclosure may be improved to increase the life of the electronic device package structure.

Each member of the electronic device package structure 100 according to the disclosure is described below.

The first chip 116 and the second chip 126 may be semiconductor chips (e.g., application processor chips), stacked memory modules, wireless local area network (WLAN)/Bluetooth modules, and the like, but are not limited thereto. The material of the first chip 116 and the second chip 126 may include silicon, silicon carbide, or gallium nitride, but the embodiments of the disclosure are not limited thereto. A first signal connection structure 118 may be provided on the surface of the first chip 116 facing the first redistribution layer structure 114 as a connection pad. The connection pad may include a structure such as a pin, a solder ball, a copper column, etc., and the first chip 116 is electrically connected to the first redistribution layer structure 114 via the first signal connection structure 118. Similarly, a second signal connection structure 128 may be provided on the surface of the second chip 126 facing the second redistribution layer structure 124 as a connection pad. The connection pad may include a structure such as a pin, a solder ball, a copper column, etc., and the second chip 126 is electrically connected to the second redistribution layer structure 124 via the second signal connection structure 128.

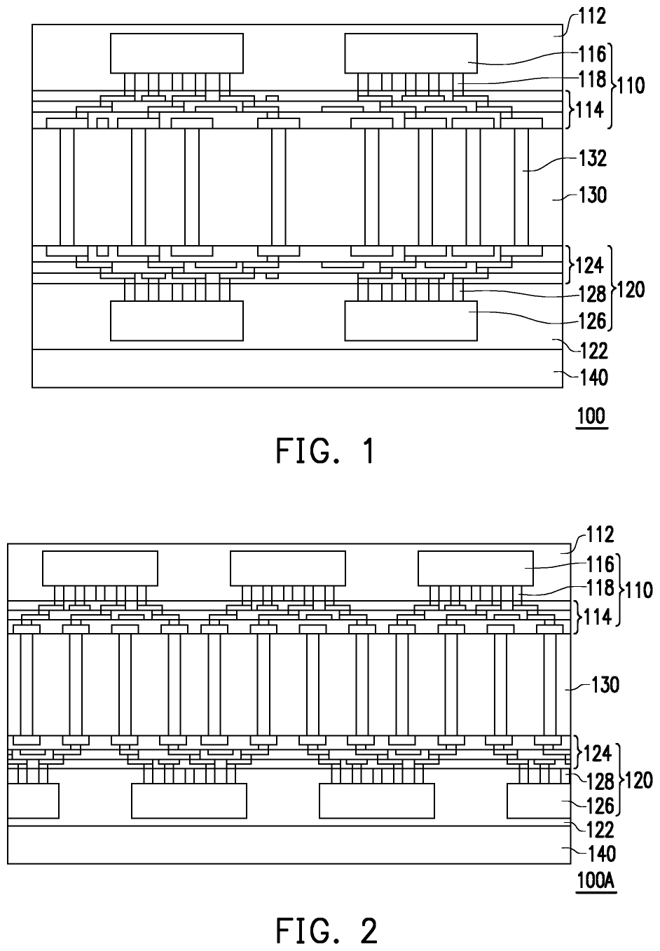

The electronic device package structure shown in FIG. 1 includes two of the first chip 116 and two of the second chips 126, and the first chips 116 and the second chips 126 are symmetrically disposed with respect to the filling layer 130. In an alternate embodiment, the number of the first chip 116 and the second chip 126 may be different and the first chip 116 and the second chip 126 may be asymmetrically disposed, as shown in an electronic device package structure 100A of FIG. 2. FIG. 2 is a cross section of an electronic device package structure according to another embodiment of the disclosure, and in the present embodiment, the numbers of the first chip 116 and second chip 126 are different and the first chip 116 and second chip 126 are asymmetrically disposed. That is to say, the numbers and configuration of the first chip 116 and the second chip 126 of the above embodiments are merely examples, and the numbers and configuration of the first chip 116 and the second chip 126 may be adjusted according to design requirements.

When a plurality of the first chip 116 are disposed, the plurality of first chips 116 may be different from each other. In other embodiments, the plurality of first chips 116 may also be identical to each other. When a plurality of the second chip 126 are disposed, the plurality of second chips 126 may be different from each other. In other embodiments, the plurality of second chips 126 may also be identical to each other.

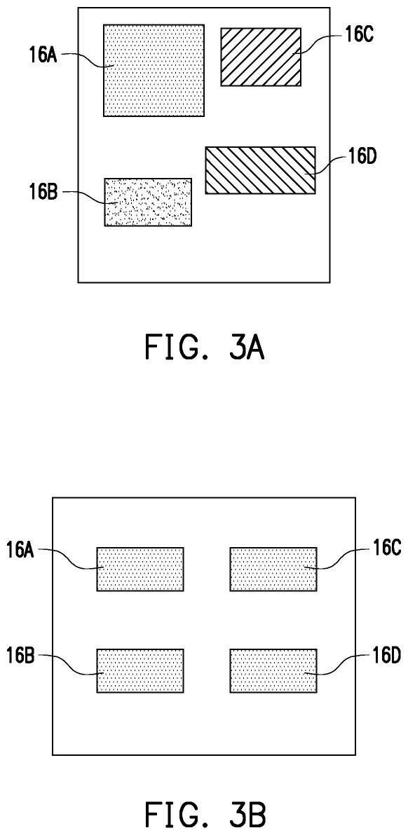

Referring to FIG. 3A and FIG. 3B, FIG. 3A and FIG. 3B are schematic diagrams illustrating configurations of chips of an electronic device package structure according to an embodiment of the disclosure. For example, the first chip 116 may include four different chips 16A, 16B, 16C, and 16D as shown in FIG. 3A, and the second chip 126 may include four identical chips 16A, 16B, 16C, and 16D as shown in FIG. 3B.

The first chip 116 and the second chip 126 may be encapsulated with an encapsulating material 112 and an encapsulating material 122, respectively. The encapsulating material 112 and the encapsulating material 122 include, for example, epoxy resin or other suitable molding materials.

Each of the first redistribution layer structure 114 and the second redistribution layer structure 124 includes a dielectric material layer and a redistribution circuit in the dielectric material layer. In some embodiments, the numbers of the dielectric material layer and the redistribution circuit of each of the first redistribution layer structure 114 and the second redistribution layer structure 124 may be more or less than the number shown in FIG. 1. The numbers of the dielectric material layer and the redistribution circuit may be adjusted according to actual needs. The material of the dielectric material layer of each of the first redistribution layer structure 114 and the second redistribution layer structure 124 includes polymer, polymide, benzocyclobutene (BCB), polybenzooxazole (PBO), or other suitable dielectric materials. The first redistribution layer structure 114 and the second redistribution layer structure 124 may use the same or different materials. The material of the redistribution circuit of the first redistribution layer structure 114 and the second redistribution layer structure 124 includes aluminum, titanium, copper, nickel, tungsten, and/or alloys thereof, but is not limited to the above materials.

The material of the filling layer 330 is, for example, polydimethylsiloxane, silica gel, epoxy resin, or acrylic resin, and the disclosure is not limited thereto. If necessary, the filling layer 330 may have a conductive through hole 132 electrically connecting the first electronic device layer 110 and the second electronic device layer 120.

In addition to providing additional electrical functionality, the functional structure 140 may also provide the function of enhancing shock prevention and impact prevention for the electronic device package structure. The functional structure 140 may include additional functional elements such as passive elements or heat dissipating elements. The functional structure 140 may be a composite layer and may include a laminate or composite layer of a soft material and a hard material. The soft material may be, for example, rubber, butadiene acrylonitrile, silica gel, or the like. The hard material may be, for example, metal, stainless steel, copper foil, or the like. The functional structure 140 may also be a patterned composite layer. The functional structure 140 may help improve the hardness and structural strength of the overall structure.

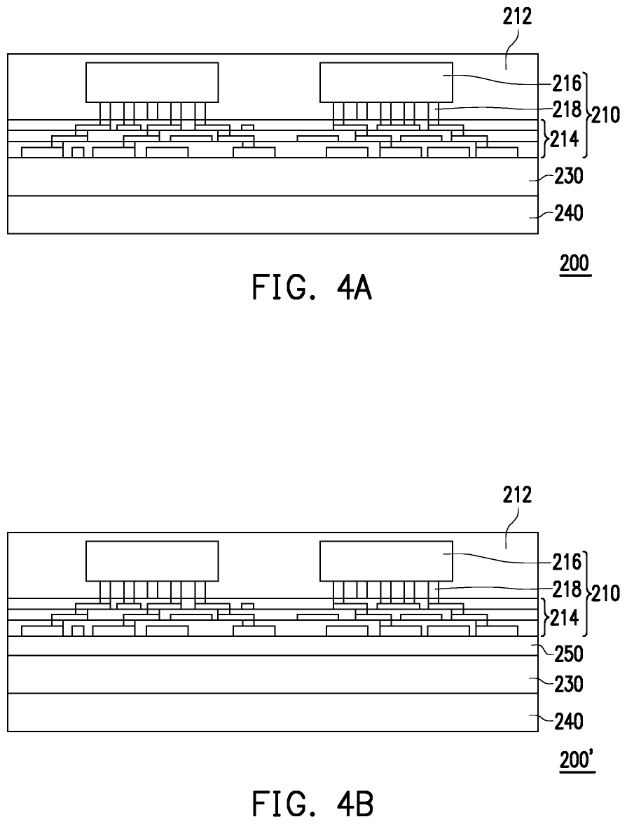

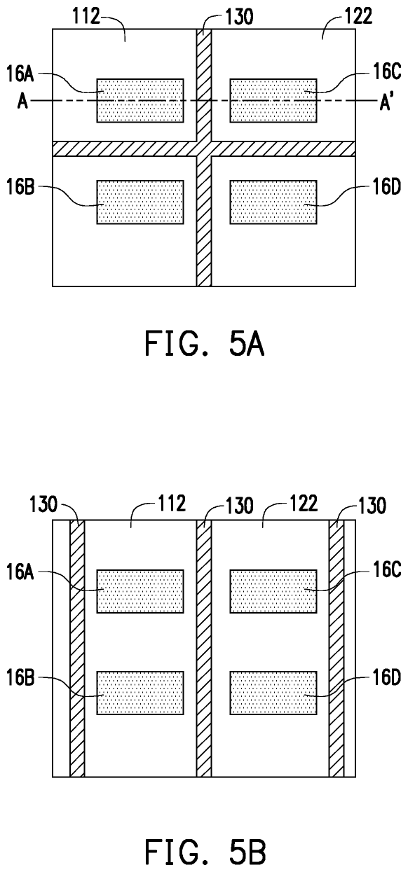

FIG. 4A is a cross section of an electronic device package structure 200 according to another embodiment of the disclosure.

Referring to FIG. 4A, the electronic device package structure 200 according to an embodiment of the disclosure includes an electronic device layer 210, a filling layer 230, and a functional structure 240. The filling layer 230 is disposed between the electronic device layer 210 and the functional structure 240. The electronic device layer 210 includes a chip 216, a redistribution layer structure 214, and a signal connection structure 218 disposed between the chip 216 and the redistribution layer structure 214. The redistribution layer structure 214 is located between the chip 216 and the filling layer 230.

The Young's modulus of the functional structure 240 is less than or equal to the Young's modulus of the electronic device layer 210, and the Young's modulus of the filling layer 230 is less than the Young's modulus of the functional structure 240. The thickness ratio of the filling layer 230 to the electronic device layer 210 is 0.6 to 10, and the thickness ratio of the filling layer 230 to the functional structure 240 is 1.2 to 50.

By controlling the thicknesses (thickness ratio and material matching) of the electronic device layer 210, the functional structure 240, and the filling layer 230 and the Young's modulus of each layer within the above ranges, the electronic device package structure 200 according to another embodiment of the disclosure may have a first neutral surface located in the electronic device layer 210, a second neutral surface located in the functional structure 240, and a third neutral surface located in the filling layer 230. The first neutral surface is adjacent to the interface of the redistribution layer structure 214 and the filling layer 230 in the electronic device layer 210, and the second neutral surface is adjacent to the interface of the functional structure 240 and the filling layer 230.

Each member of the electronic device package structure 200 is described below.

The electronic device layer 210 may at least include a chip 216, a redistribution layer structure 214, and an encapsulating material 212. The detailed descriptions of the chip 216, the redistribution layer structure 214, and the encapsulating material 212 are respectively the same as the descriptions of the first chip 116, the first redistribution layer structure 114, and the encapsulating material 112 and are not repeated herein.

The detailed description of the filling layer 230 is the same as the description of the filling layer 130 above and is not repeated herein.

In addition to providing additional electrical functionality, the functional structure 240 may also provide the function of enhancing shock prevention and impact prevention for the electronic device package structure. The functional structure 240 may include additional functional elements such as passive elements or heat dissipating elements. The functional structure 240 may be a composite layer and may include a laminate or composite layer of a soft material and a hard material. The soft material may be, for example, rubber, butadiene acrylonitrile, silica gel, or the like. The hard material may be, for example, metal, stainless steel, copper foil, or the like. The functional structure 240 may also be a patterned composite layer. The functional structure 240 may help improve the hardness and structural strength of the overall structure. The Young's modulus of the functional structure 240 may be between 115 GPa and 130 GPa. The thickness of the functional structure 240 may be between 10 microns and 300 microns, such as 50 microns, 100 microns, 150 microns, 200 microns, or 250 microns.

FIG. 4B is a cross section of an electronic device package structure 200′ according to another embodiment of the disclosure.

The electronic device package structure 200′ according to another embodiment of the disclosure is similar in structure to the electronic device package structure 200 above, except that the electronic device package structure 200′ further includes a thin film transistor layer 250 disposed between the filling layer 230 and the redistribution layer structure 214. The electronic device package structure 200′ may be, for example, an electronic device package structure applied to a micro LED or a mini LED. In this case, the chip 216 may be a light-emitting diode (LED) chip. The redistribution layer structure 214 may be omitted from the electronic device package structure 200′ if necessary.

In the electronic device package structure 200′, the overall Young's modulus of the functional structure 240 is less than or equal to the overall Young's moduli of the electronic device layer 210 and the thin film transistor layer 250, and the Young's modulus of the filling layer 230 is less than the overall Young's modulus of the functional structure 240. The ratio of the thickness of the filling layer 230 to the total thickness of the electronic device layer 210 and the thin film transistor layer 250 is 0.6 to 10, and the thickness ratio of the filling layer 230 to the functional structure 240 is 1.2 to 50.

By controlling the thicknesses (thickness ratio and material matching) of the electronic device layer 210, the thin film transistor layer 250, the functional structure 240, and the filling layer 230 and the Young's modulus of each layer within the above ranges, the electronic device package structure 200′ according to another embodiment of the disclosure may have three neutral surfaces, i.e., a first neutral surface located in the electronic device layer 210, a second neutral surface located in the functional structure 240, and a third neutral surface located in the filling layer 230. In particular, the first neutral surface is adjacent to the interface of the redistribution layer structure 214 and the filling layer 230 in the electronic device layer 210, and the second neutral surface is adjacent to the interface of the functional structure 240 and the filling layer 230.

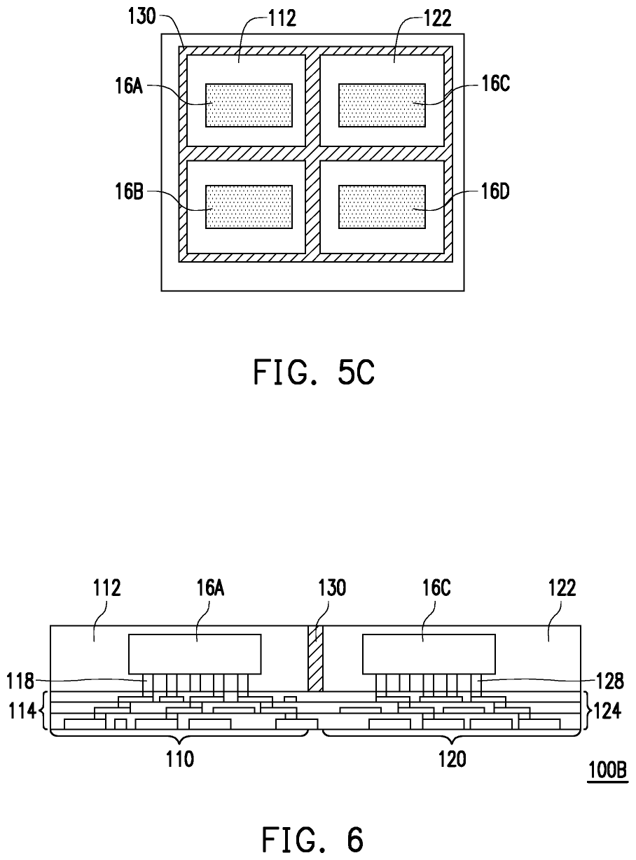

FIG. 5A to FIG. 5C are top views of an electronic device package structure according another embodiment of the disclosure. FIG. 6 is a cross section along section line A-A′ in the electronic device package structure shown in FIG. 5A.

In the present embodiment, materials having different Young's moduli may be disposed in different forms on the periphery of the chip to avoid delamination or cracking of the electronic device package structure.

Referring to FIG. 5A to FIG. 6, an electronic device package structure 100B according to an embodiment of the disclosure includes a first electronic device layer 110, a second electronic device layer 120, and a filling layer 130. The first electronic device layer 110 and the second electronic device layer 120 are disposed in a side-by-side manner. The filling layer 130 is disposed between the first electronic device layer 110 and the second electronic device layer 120. The first electronic device layer 110 includes chips 16A and 16B and a encapsulating material 112. The second electronic device layer 120 includes chips 16C and 16D and an encapsulating material 122.

The Young's modulus of the second electronic device layer 120 is less than or equal to the Young's modulus of the first electronic device layer 110, and the Young's modulus of the filling layer 130 is less than the Young's modulus of the second electronic device layer 120, and the ratio of the Young's modulus of the first electronic device layer 110 to the Young's modulus of the filling layer 130 is 10 to 1900 and the ratio of the Young's modulus of the second electronic device layer to the Young's modulus of the filling layer 130 is 7.6 to 1300. Moreover, the Young's modulus of the filling layer 130 is less than the Young's moduli of the encapsulating material 112 and the encapsulating material 122 and the Young's moduli of the encapsulating materials 112 and 122 are less than the Young's moduli of the chips 16A to 16D.

In addition to being disposed between the first electronic device layer 110 and the second electronic device layer 120, the filling layer 130 may be disposed in the encapsulating materials 112 and 122 in various forms as necessary. For example, referring to FIG. 5A, the filling layer 130 may also be disposed between the chips 16A to 16D. Referring to FIG. 5B, the filling layer 130 may also be disposed at two sides of the chips 16A to 16D. Referring to FIG. 5C, the filling layer 130 may be disposed between the chips 16A to 16D and surround the chips 16A to 16D. The filling layer 130 may be, for example, polydimethylsiloxane, silica gel, epoxy resin, or acrylic resin. The Young's modulus of the filling layer 130 is 5 GPa or less.

The filling layer 130 may help to create a neutral surface in the direction perpendicular to the layered structure of the electronic device package structure in the electronic device package structure, thereby reducing stress within the package structure.

A manufacturing method of an electronic device package structure according to the disclosure includes forming a first electronic device layer, forming a second electronic device layer, and forming a filling layer between the first electronic device layer and the second electronic device layer. The first electronic device layer has a first Young's modulus and a first thickness. The second electronic device layer has a second Young's modulus and a second thickness. The filling layer has a third Young's modulus and a third thickness. The third Young's modulus depends on the first Young's modulus and the second Young's modulus such that the ratio of the first Young's modulus to the third Young's modulus is 10 to 1900, and the ratio of the second Young's modulus to the third Young's modulus is 7.6 to 1300. Meanwhile, the third Young's modulus is less than the first Young's modulus and less than the second Young's modulus. The third thickness depends on the first thickness and the second thickness such that the ratio of the third thickness to the first thickness is 0.6 to 10, and the ratio of the third thickness to the second thickness is 1.2 to 50.

The electronic device package structure manufactured according to the manufacturing method of the disclosure may have three neutral surfaces respectively located in the first electronic device layer, the second electronic device layer, and the filling layer. As described above, when there are three neutral surfaces in the electronic device package structure, the strain on the connection structure in the electronic device package structure and the stress on the package structure may be reduced. Therefore, delamination or cracking may be reduced when the electronic device package structure is in a bent state.

### EXAMPLES

The following examples are provided to illustrate how to manufacture the electronic device package structure according to the disclosure by adjusting the Young's moduli and thicknesses of the members.

### Example 1 Different Young's Moduli

In Example 1, an electronic device package structure as shown in FIG. 1 was used, and the thicknesses of the first electronic device layer and the second electronic device layer were set to 300 μm, and the thickness of the filling layer was set to 30 μm. In actual experiments, the material of each layer may be changed to have a different Young's modulus. In the simulation test, the Young's moduli of the first electronic device layer, the second electronic device layer, and the filling layer were set according to the data listed in Table 1 below to observe the number and location of the neutral surface of the electronic device package structure samples 1A to 1C in a bent state.

TABLE 1

| | 1A | | IB | | 1C | |
|---|---|---|---|---|---|---|
| First electric device layer | 131 | GPa | 131 | GPa | 131 | GPa |
| Filling layer | 0.2 | GPa | 2 | GPa | 20 | GPa |
| Second electric device layer | 131 | GPa | 131 | GPa | 131 | GPa |

| | | | |
|---|---|---|---|
| Number of neutral surface | 3 | 3 | 1 |

According to the results of computer simulation, when the ratio of the Young's modulus of the first electronic device layer to the Young's modulus of the filling layer is greater than 65 and the ratio of the Young's modulus of the second electronic device layer to the Young's modulus of the filling layer is also greater than 65, 3 neutral surfaces are produced when the electronic device package structure sample structure is in a bent state.

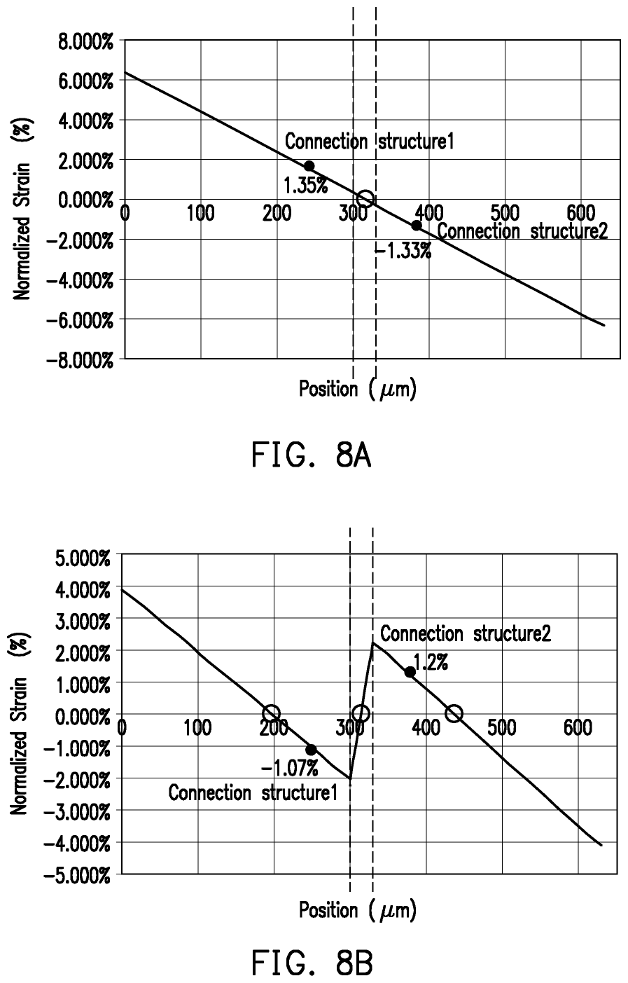

FIG. 8A is a plot showing the normalized strain on the electronic device package structure of sample 1C in example 1 with respect to the position (in a thickness direction); and FIG. 8B is a plot showing the normalized strain on the electronic device package structure of sample 1B in example 1 with respect to the position (in a thickness direction). The dotted line on the left in FIG. 8A and FIG. 8B represents the interface of the first electronic device layer and the filling layer, and the dotted line on the right represents the interface of the filling layer and the second electronic device layer. FIG. 8A shows that the electronic device package structure of example 1C has a single neutral surface only at the position corresponding to the filling layer, and the average normalized strain on the two connection structures are 1.35% and −1.33%, respectively. FIG. 8B shows that the electronic device package structure of example 1B has 3 neutral surfaces respectively located at positions corresponding to the first electronic device layer, the filling layer, and the second electronic device layer, and the average normalized strain on the two connection structures are −1.07% and 1.20%, respectively. Comparing the sum of the normalized strain at the two connection structures of example 1B and example 1C, it is observed that compared to the electronic package structure of sample 1C in example 1 having only a single neutral surface, the average normalized strain at the connection structure of the electronic package structure of sample 1B in example 1 having three neutral surfaces is reduced by 14% to 15%.

Further, the maximum normalized strain is about 6% in FIG. 8A while the maximum normalized strain is about 4% in FIG. 8B. That is, the electronic package structure of sample 1B in example 1 having a plurality of neutral surfaces may reduce strain within the package structure.

### Experimental Example 2 Thickness Variation

In example 2, an electronic device package structure as shown in FIG. 1 was used, and the Young's moduli of the first electronic device layer and the second electronic device layer were adjusted to 131 GPa, and the Young's modulus of the filling layer was adjusted to 3 GPa. The thicknesses of the first electronic device layer, the second electronic device layer, and the filling layer were adjusted according to the data listed in Table 2 below to observe the number of the neutral surface of different electronic device package structure samples in a bent state.

TABLE 2

| | 2A | 2B |
|---|---|---|
| First electric device layer | 250 microns | 250 microns |
| Filling layer | 300 microns | 300 microns |
| Second electric device layer | 250 microns | 200 microns |
| Number of neutral surface | 3 | 3 |

According to the results of computer simulation, when the ratio of the thickness of the filling layer to the thickness of the first electronic device layer is 1.2 and the ratio of the thickness of the filling layer to the thickness of the second electronic device layer is between 1.2 and 1.5, 3 neutral surfaces are produced when the electronic device package structure samples 2A and 2B are in a bent state.

Based on the above, in the electronic device package structure of an embodiment of the disclosure, by adjusting the thickness and Young's modulus of each member, a plurality of neutral surfaces may be produced. When the electronic device package structure is in a bent state, the neutral surfaces may substantially fall near an element or film layer that is easily damaged by bending stress. As such, the flexible electronic device using the electronic device package structure of an embodiment of the disclosure is not susceptible to damage due to repeated bending during use, thereby extending service life.

It will be apparent to those skilled in the art that various modifications and variations may be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An electronic device package structure, comprising:
a first electronic device layer,
a second electronic device layer; and
a filling layer disposed between the first electronic device layer and the second electronic device layer,
wherein a Young's modulus of the second electronic device layer is less than or equal to a Young's modulus of the first electronic device layer, and a Young's modulus of the filling layer is less than the Young's modulus of the second electronic device layer, and a ratio of the Young's modulus of the first electronic device layer to the Young's modulus of the filling layer is 10 to 1900 and a ratio of the Young's modulus of the second electronic device layer to the Young's modulus of the filling layer is 7.6 to 1300.

2. The electronic device package structure of claim 1, wherein the first electronic device layer and the second electronic device layer respectively comprise at least one electronic device and a encapsulating material encapsulating the at least one electronic device, wherein the Young's modulus of the filling layer is less than a Young's modulus of the encapsulating material and the Young's modulus of the encapsulating material is less than a Young's modulus of the at least one electronic device.

3. The electronic device package structure of claim 2, wherein the first electronic device layer and the second electronic device layer are disposed in a side by side manner, and the filling layer is further disposed between the at least one electronic device, at two sides of the at least one electronic device, or around the at least one electronic device.

4. The electronic device package structure of claim 1, wherein the filling layer comprises polydimethylsiloxane, silica gel, epoxy resin, or acrylic resin.

5. The electronic device package structure of claim 1, wherein the first electronic device layer and the second electronic device layer are disposed in a stacked manner, and a thickness ratio of the filling layer to the first electronic device layer is 0.1 to 10 and a thickness ratio of the filling layer to the second electronic device layer is 0.1 to 50.

6. The electronic device package structure of claim 1, wherein the first electronic device layer has a same thickness as the second electronic device layer and the Young's modulus of the filling layer is 5 GPa or less.

7. The electronic device package structure of claim 1, wherein the filling layer has a through hole, and the first electronic device layer and the second electronic device layer are electrically connected via the through hole.

8. The electronic device package structure of claim 1, wherein the first electronic device layer at least comprises a first chip and a first redistribution layer structure, wherein the first redistribution layer structure is disposed between the first chip and the filling layer, and
the electronic device package structure at least has a first neutral surface and a second neutral surface, wherein the first neutral surface is located in the first electronic device layer, and the first neutral surface is adjacent to an interface of the first redistribution layer structure and the filling layer.

9. The electronic device package structure of claim 8, wherein the second electronic device layer at least comprises a second chip and a second redistribution layer structure, wherein
the second redistribution layer structure is disposed between the second chip and the filling layer, wherein the second neutral surface is located in the second electronic device layer, and the second neutral surface is adjacent to an interface of the second redistribution layer structure and the filling layer.

10. The electronic device package structure of claim 9, wherein the second electronic device layer further comprises a functional structure.

11. The electronic device package structure of claim 1, wherein the electronic device package structure at least has first, second, and third neutral surfaces, wherein the first neutral surface is located in the first electronic device layer, the second neutral surface is located in the second electronic device layer, and the third neutral surface is located in the filling layer.

12. An electronic device package structure, comprising:
an electronic device layer and a functional structure; and
a filling layer disposed between the electronic device layer and the functional structure,
wherein a Young's modulus of the functional structure is less than or equal to a Young's modulus of the electronic device layer, and a Young's modulus of the filling layer is less than the Young's modulus of the functional structure, a thickness ratio of the filling layer to the electronic device layer is 0.6 to 10, and a thickness ratio of the filling layer to the functional structure is 1.2 to 50.

13. The electronic device package structure of claim 12, wherein a ratio of the Young's modulus of the electronic device layer to the Young's modulus of the filling layer is 26 to 1800, and a ratio of the Young's modulus of the functional structure to the Young's modulus of the filling layer is 23 to 1300.

14. The electronic device package structure of claim 12, wherein the electronic device layer at least comprises a chip and a redistribution layer structure, and the redistribution layer structure is disposed between the chip and the filling layer,
the electronic device package structure at least has a first neutral surface and a second neutral surface, wherein the first neutral surface is located in the electronic device layer, and the first neutral surface is adjacent to an interface of the redistribution layer structure and the filling layer, and
the second neutral surface is located in the functional structure, and the second neutral surface is adjacent to an interface of the functional structure and the filling layer.

15. The electronic device package structure of claim 12, wherein the electronic device package structure at least has a first neutral surface, a second neutral surface, and a third neutral surface, wherein the first neutral surface is located in the electronic device layer, the second neutral surface is located in the functional structure, and the third neutral surface is located in the filling layer.

16. A manufacturing method of an electronic device package structure, comprising
forming a first electronic device layer having a first thickness and a first Young's modulus;
forming a second electronic device layer having a second thickness and a second Young's modulus;
forming a filling layer between the first electronic device layer and the second electronic device layer, wherein the filling layer is adjusted to have a third Young's modulus according to the first Young's modulus of the first electronic device layer and according to the second Young's modulus of the second electronic device layer, and the third Young's modulus is less than the first Young's modulus and less than the second Young's modulus; and
adjusting the filling layer to have a third thickness according to the first thickness of the first electronic device layer and according to the second thickness of the second electronic device layer.

17. The manufacturing method of the electronic device package structure of claim 16, wherein a ratio of the third thickness to the first thickness is 0.6 to 10, and a ratio of the third thickness to the second thickness is 1.2 to 50.

18. The manufacturing method of the electronic device package structure of claim 16, wherein adjusting the filling layer to have the third Young's modulus according to the first Young's modulus of the first electronic device layer and according to the second Young's modulus of the second electronic device layer comprises setting a ratio of the first Young's modulus to the third Young's modulus to 26 to 1800 and setting a ratio of the second Young's modulus to the third Young's modulus to 23 to 1300.

19. The manufacturing method of the electronic device package structure of claim 16, wherein adjusting the filling layer to have the third Young's modulus according to the first Young's modulus of the first electronic device layer and according to the second Young's modulus of the second electronic device layer comprises increasing a ratio of the first Young's modulus to the third Young's modulus to greater than 65, and forming the first neutral surface, the second neutral surface, and the third neutral surface in the first electronic device layer, the second electronic device layer, and the filling layer, respectively.
